(19) United States
(12) Patent Application Publication
(10) Pub. No.: US 2001/0028255 A1
(43) Pub. Date: Oct. 11, 2001

(54) Measuring apparatus for semiconductor device

(75) Inventor: Akitoshi Endo, Tokyo (JP)

Correspondence Address: LAFF, WHITESEL, CONTE & SARET, 401 North Michigan Avenue, Chicago, IL, 60611, US

(73) Assignee: NEC Corporation

(21) Appl. No.: 09/824,180

(22) Filed: Apr. 2, 2001

(30) Foreign Application Priority Data
Apr. 3, 2000 (JP) 100262/2000

(51) Int. Cl. G01R 31/02

(52) U.S. Cl. 324/761

(57) ABSTRACT

The measuring apparatus for a semiconductor device according to the present invention includes an electrically conductive probe needle having a lower dangling part which extends vertically downward having its tip that makes contact with an object to be measured, an upper dangling part extending upward coaxially with the lower dangling part, and a bent part located between the lower dangling part and the upper dangling part for obtaining a uniform needle pressure by buffering the contact pressure during an over-drive, a printed circuit board having a wiring which is connected electrically to an end of the upper dangling part of the probe needle, and a rotational operation mechanism which acts on the bent part of the probe needle during the over-drive to cause the bent part and the lower dangling part rotate with the axis of the upper dangling part as the center.

### BACKGROUND OF THE INVENTION

1. Field of the Invention

The present invention relates to a measuring apparatus for a semiconductor device, and more particularly to a probe card which establishes electrical connection between the body of the semiconductor measuring apparatus and an IC pad.

2. Description of the Prior Art

In the manufacturing process of semiconductor integrated circuits, upon completion of the diffusion process, measurement of electrical characteristics or the like is carried out in the state of a wafer as it is, using an inspection apparatus called a tester (semiconductor device measuring apparatus). In the tester, a probe card is provided as a board for establishing electrical connection between the IC pad (electrode) and the tester body, and it is configured such that electrical connection with the IC is established by bringing probe needles equipped on the probe card into contact with the IC pad.

Referring to FIG. 10, the structure and the operation of a conventional probe card will be described in the following. FIG. 10 is a sectional view of the conventional probe card.

As shown in FIG. 10, the conventional probe card comprises a printed circuit board 22 to be connected electrically to the tester body, a probe needle 25 (only two needles are shown in the figure for simplicity) having an upper dangling part 25a with its one end connected electrically to a wiring on the printed circuit board 22 by solder 21 and bent part 25b for buffering contact pressure and a lower dangling part 25d with its tip 25c making contact with the pad, needle fixing resin 26 which fixes the probe needle 25 below the printed circuit board 22, a first guide board 23 and a second guide board 24 which guide the probe needle 25 via respective holes 23a and 24a, and a fixing frame 27 fixed to the printed circuit board 22 which fixes the needle fixing resin 26, the first guide board 23a, and the second guide board 24a in parallel to the printed circuit board 22.

In measuring electrical characteristics and the like with this configuration, a stage 29 with a wafer 28 mounted thereon is aligned by moving it in the X, Y and θ directions, and is elevated in the Z direction to bring the tips 25c of the probe needles 25 into contact with pads 28a on the surface of the pad 28.

However, since the wafer 28 is exposed to the air and a natural oxide film is formed on the surface of the pad, it is necessary for establishing electrical connection between the pad and the probe needle 25 to stick through the natural oxide film with the probe needle 25 and expose the metallic surface of the pad 28a. For this purpose, after the probe needle 25 and the pad 28a are brought into contact once by elevating the stage 29 in the Z direction, it is general to execute an over-drive in which the stage 29 is elevated further upward. As a result of the over-drive, the probe needle 25 scrapes off the natural oxide film on the surface of the pad 28a to effect an electrical connection.

Now, the probe cards can be classified roughly into lateral needle type in which the probe needles project into lateral direction (oblique direction), and vertical needle type in which the needles project into vertical direction downward. In the case of the lateral needle type, when it is subjected to an over-drive, the probe needles slide over the pads and can readily scrape off the natural oxide film because the needles are projecting into the lateral direction. However, in the case of the vertical needle type, even when it is subjected to an over-drive, it is difficult for the probe needles to slide over the pads and scrape off the natural oxide film because the contact between the probe needles and the pads is strictly vertical, giving rise to a problem that it tends to lead to a defective contact.

Accordingly, it is the object of the present invention to provide a measuring apparatus for a semiconductor device which is capable of establishing an electrical contact with the pads through sure breaking of the natural oxide film formed on the surface of the pads by the use of a probe card of the vertical needle type.

### BRIEF SUMMARY OF THE INVENTION

Objects of the Invention

It is the object of the present invention to provide a measuring apparatus for a semiconductor device which is capable of establishing an electrical contact with the pads through sure breaking of the natural oxide film formed on the surface of the pads by the use of a probe card of the vertical needle type.

Summary of the Invention

The measuring apparatus according to the present invention comprises a conductive probe needle having a lower dangling part which extends vertically downward to bring its tip into contact with an object to be measured, an upper dangling part extending coaxially upward from the lower dangling part, and a bent part situated between the lower dangling part and the upper dangling part for obtaining a uniform needle pressure by buffering the contact pressure during an over-drive, a printed circuit board having a wiring to which an end of the upper dangling part is connected electrically, and a rotational operation mechanism which acts, during the over-drive, on the bent part of the probe needle to cause the bent part and the lower dangling part rotate with the axis of the upper dangling part as the center.

### BRIEF DESCRIPTION OF THE DRAWINGS

The above-mentioned and other objects, features and advantages of this invention will become apparent by reference to the following detailed description of the invention taken in conjunction with the accompanying drawings, wherein:

FIG. 1 is a sectional view of an important part of a first embodiment of the invention;

FIG. 2 is a sectional view of an important part of the probe needle, before its rotation, of the first embodiment of the invention;

FIG. 3 is a sectional view of an important part of the probe needle, during its rotation, of the first embodiment of the invention;

FIG. 4 is a sectional view of an important part of a second embodiment of the invention;

FIG. 5 is a sectional view of an important part of the probe needle, before its rotation, of a third embodiment of the invention;

FIG. 6 is a sectional view of an important part of the probe needle, during its rotation, of the third embodiment of the invention;

FIG. 7 is a sectional view of an important part of the probe needle, before its rotation, of a fourth embodiment of the invention;

FIG. 8 is a sectional view of an important part of the probe needle, during its rotation, of the fourth embodiment of the invention;

FIG. 9 is a sectional view of an important part of the probe needle before its rotation, of a fifth embodiment of the invention; and

FIG. 10 is a sectional view of a conventional probe card.

### DETAILED DESCRIPTION OF THE INVENTION

Next, referring to the drawings, the present invention will be described.

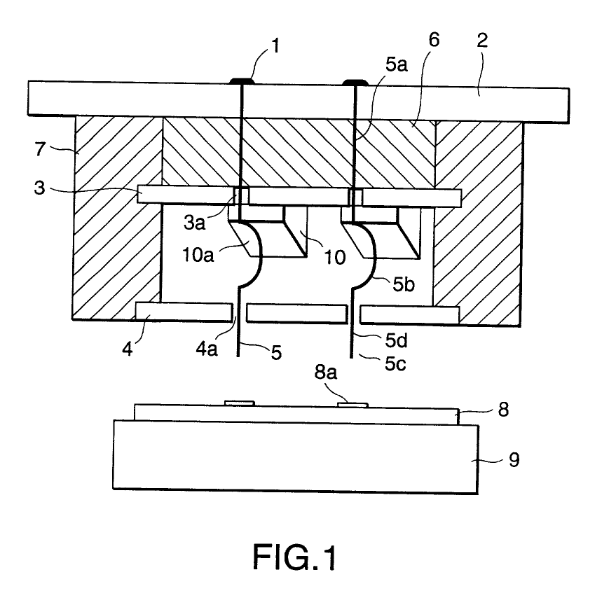

FIG. 1 is a general sectional view of a probe card for a semiconductor measuring apparatus showing a first embodiment of the present invention. This probe card comprises a printed circuit board 2 connected to the body of a measuring apparatus, a probe needle 5 (only two needles are shown in the figure for simplicity) having an upper dangling part 5a extending vertically downward having its one end connected electrically to a wiring on the printed circuit board 2, a bent part 5b and a lower dangling part 5d having its tip functioning as a contact part, needle fixing resin 6 which fixes the upper dangling part 5a of the probe needle 5 below the printed circuit board 2, a first guide board 3 and a second guide board 4 which let the probe needles pass through holes 3a and 4a, respectively, to guide them, a fixing frame body 7 which holds and fixes the first guide board 3 and the second guide board 4 in parallel to the printed circuit board 2, and a projection 10 having a sloped surface 10a formed below the first guide board 3.

Here, the sloped surface 10a of the projection 10 is inclined to the horizontal plane and is also inclined (not perpendicular) to the plane that includes the bent part 5b of the probe needle 5. During an over-drive, the bent part 5b is flexed due to the contact pressure with the wafer 8, and a part of the bent part 5b moves along the sloped surface 10a by making contact with the sloped surface 10a of the projection 10. Because of this, there is obtained a rotational (twisting) motion in a fixed direction of the tip 5c of the lower dangling part 5d, which causes the breaking of the natural oxide film on the surface of the pad 8a of the wafer and establishes a sure electrical contact between the probe needle 5 and the pad 8a. In this case, the upper dangling part 5a fixed by needle fixing resin 6 is not rotated.

The bent part 5b functions to buffer the contact pressure that the tip 5c receives from the wafer 8 due to the over-drive, and provides a uniform and stable needle pressure.

The probe needle 5 is formed of a piano wire or a wire of a conductor such as phosphor bronze, gold and tungsten, while the first and second guide boards 3 and 4 and the projection 10 are formed of an insulating material.

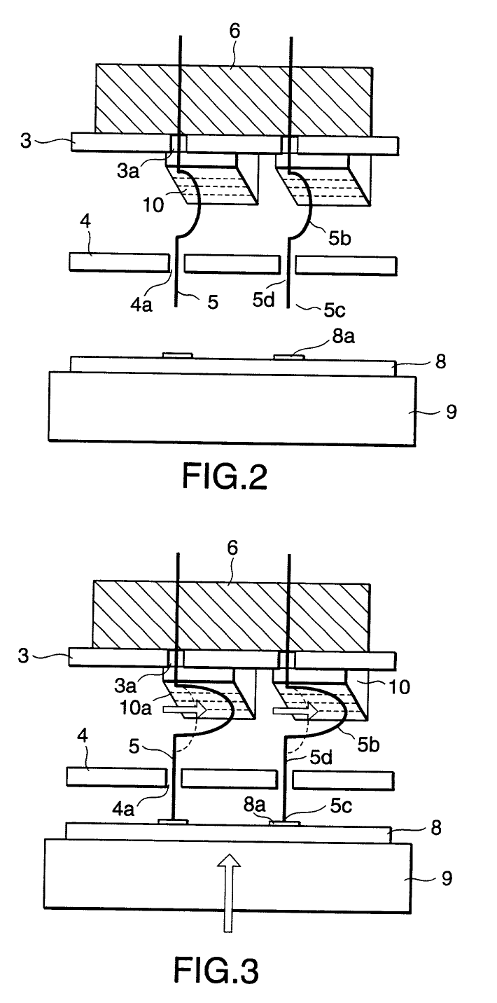

Next, referring to FIG. 2 and FIG. 3, the operation of the first embodiment of this invention will be described in more detail. FIG. 2 shows the state prior to the contact of the probe needles 5 with the wafer 8 (state prior to an over-drive), and FIG. 3 shows the state in which the probe needles 5 have established a contact with the wafer 8 (state during an over-drive). FIG. 2 and FIG. 3 are illustrating only portions that are related to the description out of the constitution in FIG. 1.

In the measurement of electrical characteristics and the like, first, the stage 9 in the state as shown in FIG. 2 with the wafer 8 mounted thereon is moved in the X, Y and θ directions for alignment.

Upon completion of the alignment, the stage 9 is elevated in the Z direction to bring the probe needles 5 into contact with the pads 8a on the surface of the wafer 8. However, in this state electrical contact of the probe needles with the pads 8a is not yet obtained because of the presence of the natural oxide film covering the surface of the wafer 8.

Then, an over-drive is introduced in this state. In this case, the probe needles 5 are pushed upward due to the contact pressure with the wafer 8, the bent parts 5b are flexed, and the bent parts 5b are brought into contact with the sloped surfaces 10a of the projections 10 provided on the lower side of the first guide board 3. In this situation, the bent part 5b makes contact with the sloped surface 10a where the plane that includes the bent part 5b makes angle with the sloped surface which is different from the normal to the sloped surface 10a, and as a result, the bent part 5b receives a rotational force which rotates the part 5b in a fixed direction.

When the over-drive is continued further in such an arrangement condition, the bent part 5b that has been seeking an escape place under the upwardly energizing force of the contact pressure from the wafer 8 and the downwardly pushing force of the sloped surface 10a escapes upward along the sloped surface 10a. Then, the lower part of the bent part 5b and the lower dangling part 5d of the probe needle 5 rotate toward the front of the plane of the figure as shown in FIG. 3, and the tip 5c of the probe needle 5 is also rotated in the same direction. As a result, the tip 5c scrapes the natural oxide film off the wafer surface 8 and an electrical contact between the probe needle 5 and the pad 8a situated beneath the natural oxide film becomes possible. In this way, breaking of the oxide film by the combination of the pressing and rotational forces on the tip 5c becomes possible according to this invention, instead of the mere pressing by the tip of the probe needle in the conventional technique. Accordingly, breaking of the natural oxide film can be accomplished with high reliability, and surer electrical contact between the probe needles 5 and the pads 8a can be realized.

Upon finish of the over-drive, no more sliding over the sloped surface of the bent part takes place, the rotation of the probe needle 5 stops, and the preparation for the measurement is completed.

With the completion of the measurement the stage 9 is lowered. The probe needle 5 is rotated in the direction opposite to that at its elevation, returning to the initial state shown in FIG. 2. Here, by constructing the device such that all of the probe needles are rotated in the same direction simultaneously, it is possible to avoid the contact of adjacent needles.

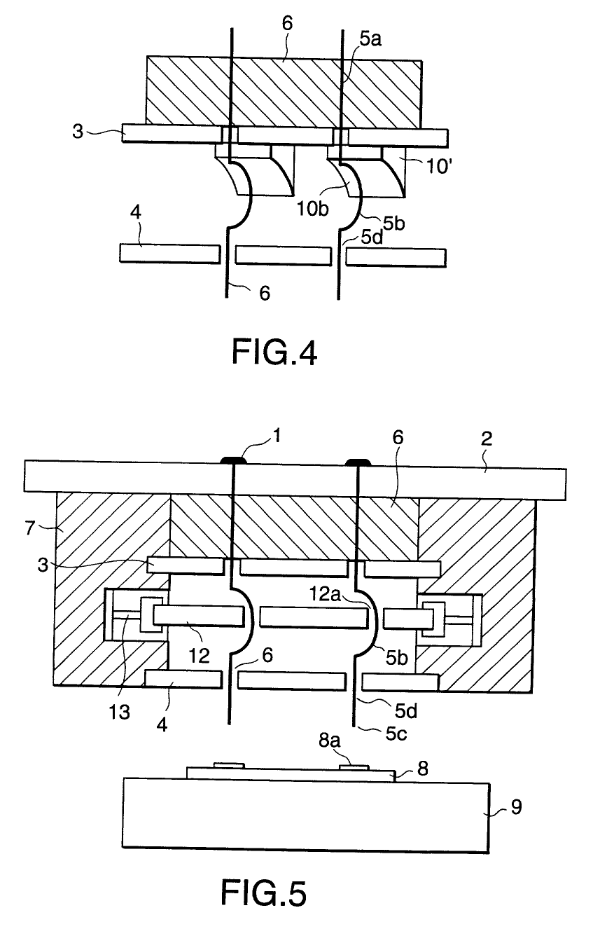

FIG. 4 is a sectional view showing an important part of a second embodiment of the invention. A difference of this embodiment from the first embodiment in FIG. 1 is that the sloped surface 10b of a projection 10′ is formed in a curved surface. In this case, the sloped surface is formed such that when the bent part 5b makes contact with the curved sloped surface 10b, the normal to the sloped surface at the contact point of the bent part 5b to the curved surface 10b is not parallel to the plane that includes the bent part 5b. Accordingly, when the device is subjected to an over-drive, the bent part 5b and the lower dangling part 5d rotate along the sloped surface 10b.

The form of the sloped surface of the projection is not limited to those shown in FIG. 1 and FIG. 4, and may have any form provided that it makes contact with the bent part and causes the bent part to rotate.

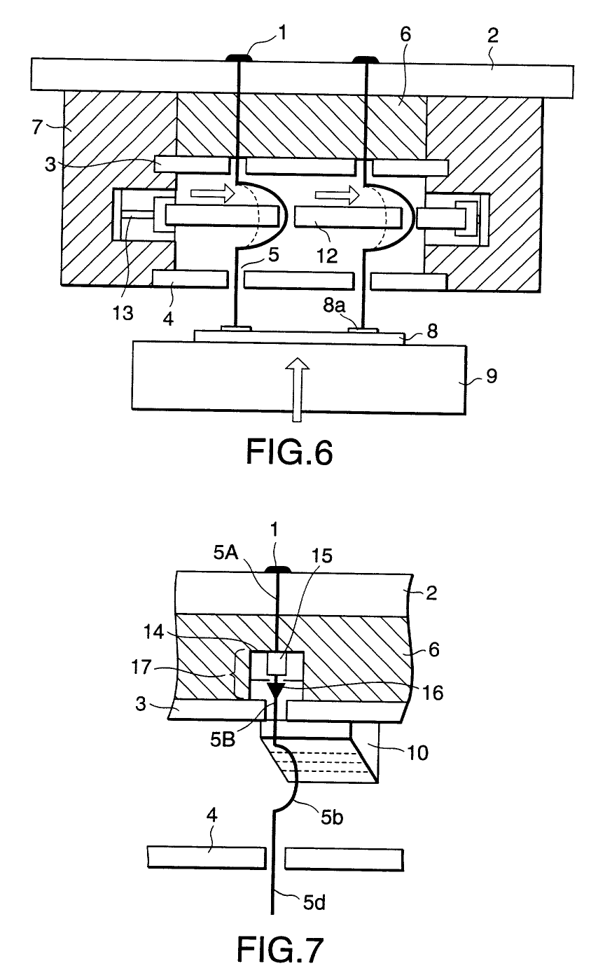

FIG. 5 and FIG. 6 are sectional views showing a third embodiment of the invention. FIG. 5 shows the state of the device prior to an over-drive, and FIG. 6 shows the state during the over-drive.

In the probe card of this embodiment, a third guide board 12 made of an insulating material is arranged between the first guide board 3 and the second guide board 4 in place of the projection 10 of the first embodiment, the third guide board 12 is moved by a drive device 13, and the bent part 5b of each probe needle 5 is rotated in a predetermined direction via a hole 12a in the third guide board 12.

More specifically, the drive device 13 grips each end of the third guide board 12 by an arm, and moves the third guide board 12 so as to cause the hole 12a rotate with the axis of the probe needle 5 as the center when the device 13 receives an electrical signal or the like at an over-drive. With this arrangement, the bent part 5b of the probe needle 5 inserted to the hole 12a of the third guide board 12 is forcibly rotated with the axis of the probe needle 5 as the center, and as a result, the tip 5c is also rotated on the pad 8a, and scrapes off the natural oxide film formed on the surface of the pad 8a.

In the first to third embodiments, the upper dangling part 5a of the probe needle 5 is fixed with a resin or the like so that the rotational angle of the probe needle 5 is restricted. With this in mind, in the fourth embodiment, the upper dangling part of the probe needle is separated into an upper probe needle and a lower probe needle, and an extension of the rotational angle of the probe needle is aimed at by inserting an auxiliary rotational angle expansion mechanism between the upper probe needle and the lower probe needle.

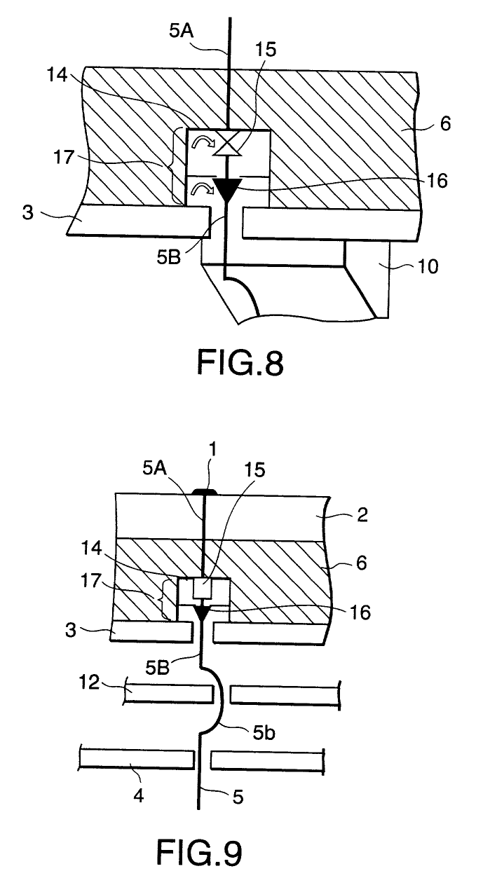

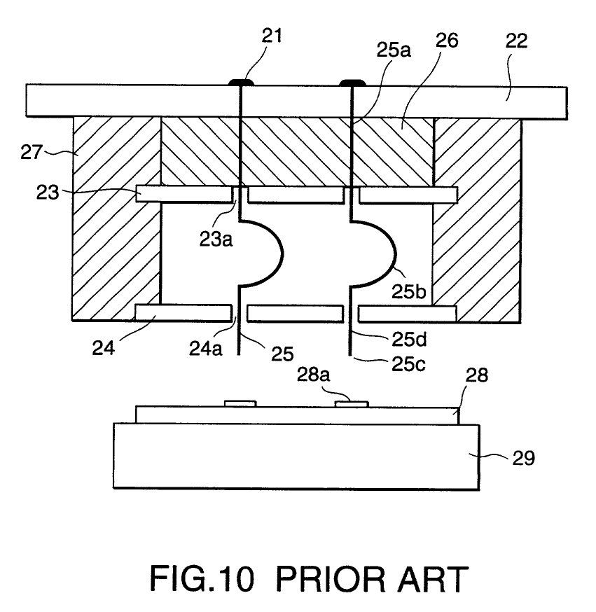

FIG. 7 and FIG. 8 are sectional views of a fourth embodiment of the invention obtained by installing a rotational angle expansion mechanism to the structure (first embodiment) in FIG. 1. The probe needle 5 of the fourth embodiment of the invention is composed of an upper probe needle 5A, a lower probe needle 5B and a connection part 17. The connection part 17 which corresponds to the rotational angle expansion mechanism consists of a box-like rotational mechanism frame 14 formed of an electrically conductive body, a plate-like rotating body 15 with its one end fixed to the inner ceiling of the frame 14 and the other end connected to the lower probe needle 5B, and a current carrying member 16 provided on the outside of the rotational mechanism frame 14 of the lower probe needle 5B. The current carrying member 16 is set apart from the rotational mechanism frame 14 prior to the start of an over-drive. The rotational mechanism frame 14 is joined fixedly to the upper probe needle 5A, and its periphery is fixed with a needle fixing resin in the same way as in the upper probe needle 5A as shown in FIG. 7. The rotating body 15 is made of a soft material having a restoring force that brings it back to its initial state even when a twisting force is applied to it.

With this constitution, during an over-drive, although the upper probe needle 5A and the rotational mechanism frame 14 remain immobile fixed by the needle fixing resin 6, the rotating body 15 can readily be twisted (rotated) because of its being made of a soft material, and an expansion of the rotational angle can be achieved (see FIG. 8). Moreover, in this embodiment, during the over-drive, the current carrying member 16 provided in the lower probe needle 5B is pressed against the lower side of the rotational mechanism frame 14 due to the contact pressure with the wafer 8, which establishes electrical connection between the rotational mechanism frame 14 and the lower probe needle 5B.

The rotational angle expansion mechanism is applicable also to the other embodiments. The structure in which the rotational angle expansion mechanism is applied to the third embodiment is shown as a fifth embodiment in FIG. 9.

In the above the present invention has been described with reference to preferred embodiments, but this invention is not limited to these embodiments alone and can be modified appropriately within the scope that does not deviate from the spirit of the invention. For example, the rotating body 15 that has been described as having a plate-like form may be given a columnar form made of a soft material. Moreover, the rotating body 15 may be made of a conductive body. In that case, the current carrying member 16 may be dispensed with. Furthermore, the projections 10 and 10′ may be formed of a conductive material.

As described in the above, the object of the present invention is to realize a mechanism by which the lower part of the probe needle is rotated by the application of a rotating force to the bent part of the probe needle during the over-drive. Therefore, according to the present invention, it is possible to provide a semiconductor device measuring apparatus of the vertical needle type in which the lower part of the probe needles can surely break the natural oxide film formed on the surface of the pad and establish electrical connection with the pad. Furthermore, by combining the construction just described with the rotational angle expansion mechanism, a larger rotational angle of the needles can be obtained to increase the breaking power to the natural oxide film and establish a more reliable electrical contact of the needles with the pad.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A measuring apparatus for a semiconductor device comprising:
an electrically conductive probe needle having a lower dangling part extending vertically downward having a tip that makes contact with an object to be measured, an upper dangling part extending above said lower dangling part coaxially with it, and a bent part interposed between said lower dangling part and said upper dangling part for providing a uniform needle pressure during an over-drive,
a printed circuit board having a wiring which is electrically connected to an end of the upper dangling part of said probe needle, and a
rotational operation mechanism which acts on said bent part of said probe needle during said over-drive that cause said bent part and said lower dangling part to rotate with the axis of said upper dangling part as the center.

2. The measuring apparatus for a semiconductor device as claimed in claim 1 further comprising: a first guide board held horizontally above said bent part of said probe needle having guide holes opened therein for guiding said probe needles, and a second guide board held horizontally below said bent part of said probe needle having guide holes for guiding said probe needles.

3. The measuring apparatus for a semiconductor device as claimed in claim 1, wherein said rotational operation mechanism is installed in the vicinity of said bent part, and includes a sloped surface which makes contact with said bent part during said over-drive to guide the bent part so as to cause a rotation of the bent part.

4. The measuring apparatus for a semiconductor device as claimed in claim 3, wherein said sloped surface is a planar or curved surface for which the normal drawn at the contact part with said bent part is not parallel to the plane that includes said bent part.

5. The measuring apparatus for a semiconductor device as claimed in claim 1, wherein said rotational operation mechanism includes a moving member which constrains a part of said bent part during said over-drive and moves so as to forcibly cause said bent part and said lower dangling part to rotate around the axis of said upper dangling part, and a drive means for causing said moving member to move, where said drive means causes said moving member to move by receiving a signal during said over-drive.

6. The measuring apparatus for a semiconductor device as claimed in claim 5, wherein said moving member is a guide board having a guide hole opened for guiding a part of each of said bent part, held freely movably in the horizontal plane, and said drive means moves said guide board in the horizontal plane.

7. The measuring apparatus for a semiconductor device as claimed in claim 1, wherein said probe needle is divided in the middle of said upper dangling part, and a rotational angle promoting mechanism for expanding the rotational angle of said bent part and said lower dangling part during said over-drive is inserted at the dividing part.

8. The measuring apparatus for a semiconductor device as claimed in claim 7, wherein said rotational angle promoting mechanism includes a rotational angle expansion mechanism which mechanically connects the portion of the upper dangling part on said printed circuit board side and the portion of the upper dangling part on said bent part side and expands the rotational angle of said bent part and said lower dangling part during said over-drive, and an electrical connection mechanism which electrically connects the portion of the upper dangling part on said printed circuit board side and the portion of the upper dangling part on said bent part side during said over-drive.

9. The measuring apparatus for a semiconductor device as claimed in claim 8, wherein said rotational angle expansion mechanism is composed of a rotating body made of a soft material, and said electrical connection mechanism consists of a box-like rotational mechanism frame made of a conductive body which is connected electrically to the portion of the upper dangling part on said printed circuit board side and has a hole opened for passing the portion of the upper dangling part on said bent part side on its lower surface, and a current carrying member fixed to the portion of the upper dangling part on said bent part side which makes contact with the outer surface of said rotational mechanism frame when said bent part is flexed during the over-drive, and further, said rotating body is contained in said rotational mechanism frame and has its upper end fixed to the inner ceiling of said rotational mechanism frame.
